(19) United States
(12) Patent Application Publication
(10) Pub. No.: US 2026/0123064 A1
(43) Pub. Date: Apr. 30, 2026

(54) ROBUST INFRARED IMAGING SENSOR

(71) Applicant: Triad National Security, LLC, Los Alamos, NM (US)

(72) Inventor: Glen Anthony WURDEN, Los Alamos, NM (US)

(21) Appl. No.: 19/352,910

(22) Filed: Oct. 8, 2025

Related U.S. Application Data
(60) Provisional application No. 63/711,966, filed on Oct. 25, 2024.

(51) Int. Cl. H10F 30/29; H10F 39/00

(52) U.S. Cl. CPC H10F 30/29; H10F 39/024; H10F 39/805

(57) ABSTRACT

Infrared imaging sensors and methods for producing same are provided herein. An example infrared imaging sensor includes a substrate, one or more x-ray absorber layers, and a black intermediate layer disposed between the substrate and the one or more x-ray absorber layers. Example substrates include sapphire disks, sapphire windows, diamond substrates, germanium substrates, and silicon substrates.

### CROSS-REFERENCE TO RELATED APPLICATION(S)

The present application claims priority to and benefit of U.S. Provisional Application Ser. No. 63/711,966, titled “ROBUST INFRARED IMAGING SENSOR”, filed Oct. 25, 2024, the entire contents of which are incorporated herein by reference.

### STATEMENT REGARDING GOVERNMENT SUPPORT

This invention was made with government support under 89233218CNA000001 awarded by the National Nuclear Security Administration. The government has certain rights in the invention.

### TECHNOLOGICAL FIELD

Example embodiments of the present disclosure relate generally to imaging bolometers, and more particularly, to robust infrared imaging sensors and methods for producing same.

### BACKGROUND

A bolometer is a diagnostic tool typically used to measure the radiation emitted by fusion plasma. One type of bolometer used on fusion plasma experiments around the world is an imaging bolometer, which employs infrared (IR) imaging of a thin foil sensor to detect the resulting change in temperature resulting from the heating thereof by the incident radiation from the plasma. The inventor has identified a number of deficiencies and problems in the conventional thin foil sensors of such imaging bolometers. Through applied effort, ingenuity, and innovation, many of these identified deficiencies and problems have been solved by developing solutions that are structured in accordance with the embodiments of the present disclosure, many examples of which are described in detail herein.

### BRIEF SUMMARY

Various embodiments of the present disclosure are directed to robust infrared imaging sensors and methods for producing same. In accordance with some exemplary embodiments of the present disclosure, an infrared imaging sensor is provided, the infrared imaging sensor including a substrate, one or more x-ray absorber layers, and a black intermediate layer disposed between the substrate and the one or more x-ray absorber layers.

In some embodiments, the substrate comprises sapphire, diamond, germanium, or silicon.

In some embodiments, the substrate is approximately 1-3 mm thick.

In some embodiments, the one or more x-ray absorber layers comprise a high-z material. In some further embodiments, the one or more x-ray absorber layers comprise gold, platinum, or tantalum. In some embodiments, the one or more x-ray absorber layers are approximately 1-5 microns thick.

In some embodiments, the infrared imaging sensor comprises a plurality of macropixels, a first set of the plurality of macropixels comprising a first x-ray absorber layer of the one or more x-ray absorber layers and a second set of plurality of macropixels comprising a second x-ray absorber layer of the one or more x-ray absorber layers, wherein the second x-ray absorber layer is thinner than the first x-ray absorber layer. In some further embodiments, the first x-ray absorber layer is approximately 2-3 microns thick and the second x-ray absorber layer is approximately 0.2-0.5 microns thick. In still some further embodiments, the second x-ray absorber layer is disposed between the black intermediate layer and a blackening layer. In still some other embodiments, a first subset of the first x-ray absorber layer is disposed between the black intermediate layer and a blackening layer.

In some embodiments, the black intermediate layer comprises Black 3.0™, Black 4.0™, or Vantablack™.

In some embodiments, the black intermediate layer has an equivalent thickness of 5-100 microns.

In some embodiments, the black intermediate layer has an equivalent thickness of approximately 5 microns.

In some embodiments, the infrared imaging sensor further includes an anti-reflection coating disposed on a side of the substrate opposite the x-ray absorber layer and black intermediate layer.

In some embodiments, the infrared imaging sensor further includes a blackening layer, wherein the one or more x-ray absorber layers are disposed between the black intermediate layer and the blackening layer. In some further embodiments, the blackening layer is approximately 0.1-5 microns thick. In certain embodiments, the blackening layer is thinner than the black intermediate layer.

In another exemplary embodiment of the present disclosure, a method of forming an infrared imaging sensor is provided, the method including providing a supporting substrate, the supporting substrate having a first surface and a second, opposing surface, depositing an anti-reflection coating on the first surface of the supporting substrate, depositing a black intermediate layer on the second, opposing surface of the supporting substrate, and depositing one or more x-ray absorber layers onto the black intermediate layer.

In some embodiments, example methods further include depositing a blackening layer onto the one or more x-ray absorber layers.

In some embodiments, depositing the black intermediate layer on the second surface of the supporting substrate comprises using an airbrush paint sprayer.

In some embodiments, depositing the one or more x-ray absorber layers onto the black intermediate layer comprises overcoating a high-Z material onto the black intermediate layer via a vacuum sputtering deposition process.

In another exemplary embodiment of the present disclosure, an imaging bolometer is provided, the imaging bolometer including an IR camera, a pinhole, and an infrared imaging sensor, the infrared imaging sensor including a substrate, one or more x-ray absorber layers, and a black intermediate layer disposed between the substrate and the one or more x-ray absorber layers.

In some embodiments, the imaging bolometer further includes one or more relay mirrors.

In some embodiments, the substrate comprises a sapphire disk.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the present disclosure in any way. It will be appreciated that the scope of the present disclosure encompasses many potential embodiments in addition to those here summarized, some of which will be further described below. Other features, aspects, and advantages of the subject matter will become apparent from the description, the drawings, and the claims.

### BRIEF DESCRIPTION OF THE DRAWINGS

Having thus described certain example embodiments of the present disclosure in general terms above, non-limiting and non-exhaustive embodiments of the subject disclosure will now be described with reference to the accompanying drawings which are not necessarily drawn to scale. The components illustrated in the accompanying drawings may or may not be present in certain embodiments described herein. Some embodiments may include fewer (or more) components than those shown in the figures in accordance with an example embodiment of the present disclosure.

FIG. 1 schematically illustrates an example infrared imaging sensor structured in accordance with various example embodiments of the present disclosure.

FIG. 2 illustrates an example black intermediate layer structured in accordance with various example embodiments of the present disclosure.

FIG. 3 illustrates an example x-ray absorber layer structured in accordance with various example embodiments of the present disclosure.

FIG. 4 depicts an example infrared imaging sensor structured in accordance with various example embodiments of the present disclosure.

FIG. 5 depicts a flowchart broadly illustrating a series of steps that are performed to fabricate an infrared imaging sensor structured in accordance with an example embodiment of the present disclosure.

FIGS. 6A-6C depict performance data of a conventional gold film.

FIGS. 7A and 7B depict performance data of a conventional platinum film.

FIGS. 8A and 8B depict performance data of an example infrared imaging sensor structured in accordance with various example embodiments of the present disclosure.

FIG. 9 depicts an example mask structured in accordance with various example embodiments of the present disclosure.

FIG. 10 schematically depicts three example macropixels of an energy resolving infrared imaging sensor used in an energy resolving imaging bolometer according to various embodiments of the present disclosure.

FIGS. 11A-11C depict various masks used in forming an energy resolving infrared imaging sensor used in an energy resolving imaging bolometer according to various embodiments of the present disclosure.

### DETAILED DESCRIPTION

Example embodiments now will be more fully described with reference to the accompanying drawings, wherein like reference numerals are used to refer to like elements throughout. In the following description, for purposes of explanation, numerous specific details are set forth in order to provide a thorough understanding of the various embodiments. It is evident, however, that the various embodiments can be practiced without these specific details. It should be understood that some, but not all, embodiments of the present disclosure are shown and described herein. Indeed, embodiments of the present disclosure may be embodied in many different forms, and accordingly this disclosure should not be construed as limited to the embodiments set forth herein; rather, these embodiments are provided so that this disclosure will satisfy applicable legal requirements.

### Overview

In the case of an IR imaging bolometer, a free-standing thin metal foil (a few microns thick and made of gold or platinum) is typically used as the sensor. The thin metal foil has a large area (˜100 cm²), typically blackened on the side facing the fusion plasma for better visible and UV absorption and is used to stop soft x-rays emitted by the fusion plasma. The thin foil operates as the sensor for a pinhole camera (e.g., an IR camera, typically in the mid-IR range of 3-5 micron wavelength band), which images the temperature rise of the thin foil due to the incident radiation from the plasma, such imaging occurring on the side facing away from the fusion plasma. IR imaging bolometers using such conventional free-standing thin metal foil sensors, however, suffer from significant barriers.

Such large area thin metal foils are difficult to manufacture and mount, are delicate, may be nonuniform (e.g., variations in thickness) and/or have pinholes, and are often subject to mechanical breakage, such as from handling, vacuum pump-down or venting, and especially from disruptions in a tokamak. For example, when the chamber in which a thin foil sensor assembly is placed is vacuum pumped-down from air, if there is any air trapped behind the sensor assembly, the thin foil can break. In another example, plasma machines, such as a tokamak, can lose current very quickly, thereby generating huge forces which bang on the whole machine. Such forces can break the thin foil. The inventor has determined it would be desirable and advantageous to provide a more robust sensor that is simple to manufacture uniformly and allow for a wider range of applications for the IR imaging bolometer technology.

To overcome these problems and others, various embodiments of the present disclosure are directed to robust infrared imaging sensors and methods for producing same. In some example embodiments of the present disclosure, an infrared imaging sensor utilizes a mechanical substrate, such as a sapphire disk which is optically transparent to mid-IR wavelengths and robust against transient phenomena, to provide an improved and more robust sensor than conventional thin metal foils.

The inventor has determined that, in addition to a mechanical substrate, a black intermediate layer disposed between the substrate and a high-Z x-ray absorber material would be desirable and advantageous to function as a blackbody re-emitting layer in order to re-emit the IR light, which is emitted by the temperature of the high-Z x-ray absorber material, while also acting as a modest thermal insulator. In other words, the thermal characteristics of the substrate (e.g., large heat capacity) may cause the substrate cooling to be too strong if the high-Z x-ray absorber material directly interfaces with the supporting substrate. In addition, the inventor has determined that such a black intermediate layer can reduce the reflections of the side of the high-Z x-ray absorber material facing the IR camera. In some example embodiments, the inventor has also determined that an anti-reflection coating disposed on the back side of the substrate, which is the side facing the IR camera, can reduce reflections and allow more IR light to reach the camera.

The inventor has identified that infrared imaging sensors structured in accordance with various embodiments of the present disclosure promote a more radially localized heat signal than conventional thin metal foil sensors due to strong axial cooling down into the substrate with shorter temperature decay times.

These characteristics as well as additional features, functions, and details are described below. Similarly, corresponding and additional embodiments are also described below. The various implementations of the infrared imaging sensor of the present disclosure are not limited to imaging bolometers and can instead be configured for use with other technologies that might be of interest to a user. That is, one of ordinary skill in the art will appreciate that the infrared imaging sensor related concepts discussed herein may be applied to a wide variety of other diagnostic tools, such as a calorimeter.

### Exemplary Embodiments of the Present Disclosure

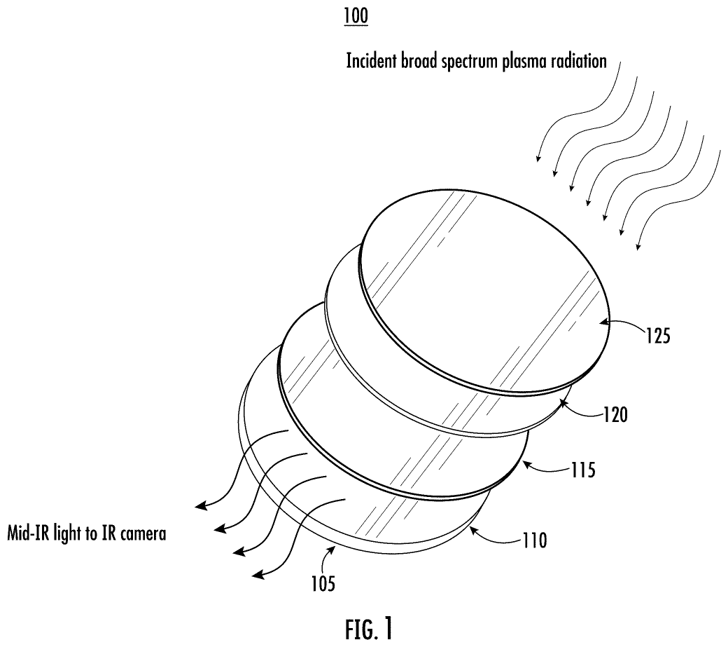

FIG. 1 schematically depicts an example infrared imaging sensor 100 according to various embodiments of the present disclosure. As shown in FIG. 1, an infrared imaging sensor 100 may comprise a multi-layer coated supporting substrate 110. The substrate 110 may be formed from any of a variety of materials that are optically transparent to mid-IR wavelengths and which provide sufficient mechanical support against transient phenomena (such as during pump-down or rapid venting or during disruptions). For example, in some embodiments, the substrate 110 may be a sapphire disk. In other example embodiments, the substrate 110 may comprise diamond, germanium, or silicon.

The present disclosure contemplates that the substrate 110 may be of any suitable shape as needed for the specific diagnostic implementation. For example, as depicted in FIG. 1, in some embodiments, the substrate 110 may be circular such that the imaging sensor 100 serves as a drop-in replacement to existing IR bolometer systems. In still other embodiments, the substrate 110 may be elongated, square, rectangular, etc.

In some embodiments, the substrate 110 may be sized as needed for the application. For example, in some embodiments, the diameter or width of the substrate 110 of the present disclosure may be between 50-200 mm. For example, in some embodiments, the substrate 110 may be sized (e.g., approximately 135 mm in diameter) such that the imaging sensor 100 serves as a drop-in replacement to existing IR bolometer systems. In some embodiments, the substrate 110 may be manufactured up to the size of available substrate materials, such as machine grown sapphire crystals (e.g., approximately 200 mm in diameter). In still other embodiments, the substrate 110 may be formed from a plurality of such available substrate materials combined together such that the diameter or width is greater than 200 mm.

In some embodiments, the thickness of the substrate 110 of the present disclosure may be between 1.0 and 5.0 mm. For example, the substrate thickness in some embodiments is less than about 5.0 mm, less than about 4.9 mm, less than about 4.8 mm, less than about 4.7 mm, less than about 4.6 mm, less than about 4.5 mm, less than about 4.4 mm, less than about 4.3 mm, less than about 4.2 mm, less than about 4.1 mm, less than about 4.0 mm, less than about 3.9 mm, less than about 3.8 mm, less than about 3.7 mm, less than about 3.6 mm, less than about 3.5 mm, less than about 3.4 mm, less than about 3.3 mm, less than about 3.2 mm, less than about 3.1 mm, less than about 3.0 mm, less than about 2.9 mm, less than about 2.8 mm, less than about 2.7 mm, less than about 2.6 mm, less than about 2.5 mm, less than about 2.4 mm, less than about 2.3 mm, less than about 2.2 mm, less than about 2.1 mm, less than about 2.0 mm, less than about 1.9 mm, less than about 1.8 mm, less than about 1.7 mm, less than about 1.6 mm, less than about 1.5 mm, less than about 1.4 mm, less than about 1.3 mm, less than about 1.2 mm, or less than about 1.1 mm.

In some embodiments, the substrate thickness is greater than about 1.0 mm, greater than about 1.1 mm, greater than about 1.2 mm, greater than about 1.3 mm, greater than about 1.4 mm, greater than about 1.5 mm, greater than about 1.6 mm, greater than about 1.7 mm, greater than about 1.8 mm, greater than about 1.9 mm, greater than about 2.0 mm, greater than about 2.1 mm, greater than about 2.2 mm, greater than about 2.3 mm, greater than about 2.4 mm, greater than about 2.5 mm, greater than about 2.6 mm, greater than about 2.7 mm, greater than about 2.8 mm, greater than about 2.9 mm, greater than about 3.0 mm, greater than about 3.1 mm, greater than about 3.2 mm, greater than about 3.3 mm, greater than about 3.4 mm, greater than about 3.5 mm, greater than about 3.6 mm, greater than about 3.7 mm, greater than about 3.8 mm, greater than about 3.9 mm, greater than about 4.0 mm, greater than about 4.1 mm, greater than about 4.2 mm, greater than about 4.3 mm, greater than about 4.4 mm, greater than about 4.5 mm, greater than about 4.6 mm, greater than about 4.7 mm, greater than about 4.8 mm, or greater than about 4.9 mm. For example, in certain embodiments, the substrate 110 is between approximately 1.0 and 3.0 mm thick. In still further embodiments, the substrate 110 is approximately 3.0 mm thick.

In some embodiments, the substrate 110 may comprise a sapphire disk. In other embodiments, the substrate 110 may be a sapphire window disposed in a vacuum flange, which uses metal seals to achieve vacuum conditions. For example, a vacuum window (e.g., salt window, zinc selenide, or sapphire) is typically used to be able to look into the plasma machine. In some embodiments, a sapphire window can be bonded into a vacuum flange, such as a commercially available ConFlat® flange. Such a sapphire window, approximately 3 mm thick, can serve as the substrate 110 as described herein and provide the potential advantage of not requiring a separate window for viewing the plasma machine.

As shown in FIG. 1, in some embodiments, the infrared imaging sensor 100 may comprise an anti-reflection coating 105. An anti-reflection coating is a type of optical coating applied to a surface of the substrate 110 to increase throughput and reduce reflection. In some embodiments, an anti-reflection coating 105 is disposed on one side of the substrate 110. For example, in some embodiments, an anti-reflection coating 105 is coated on the back side of the substrate 110, which is the side facing the IR camera. In some embodiments, the anti-reflection coating may be 3-5 μm for a mid-IR camera. In other embodiments, the anti-reflection coating may be 8-10 μm for a long-IR camera. The inventor has determined that there is approximately 8% loss on each surface for the IR light and the anti-reflection coating 105 reduces reflections and allows more IR light to reach the camera. Thickness of anti-reflection coating 105 may vary and may be determined as needed for the specific application. The anti-reflection coating 105 will decrease the IR reflections at the first sapphire-air gap, from ˜7% (uncoated) to less than ˜1% over the specified wavelength range, for example 3-5 μm for a mid-IR camera or 8-12 microns for a long-IR camera.

As shown in FIG. 1, in some embodiments, the infrared imaging sensor 100 may comprise a black intermediate layer 115. In some embodiments, the black intermediate layer 115 is disposed on one side of the substrate 110. For example, in some embodiments, the black intermediate layer 115 is coated on the front side of the substrate 110, which is the side facing the plasma during operation. The black intermediate layer 115 advantageously functions as a blackbody re-emitting layer. That is the black intermediate layer 115 re-emits the IR light being emitted by the temperature of the x-ray absorber layer 120, toward the IR camera. The black intermediate layer 115 also advantageously acts as a modest thermal insulator for x-ray absorber layer 120. For example, the measured signal may be too small if the substrate 110 absorbs the heat generated by the x-ray absorber layer 120 too efficiently.

In some embodiments, the black intermediate layer 115 exhibits a high blackbody emissivity in the IR wavelengths (2=1-12 μm). For example, in some embodiments, the emissivity of the black intermediate layer 115 is greater than 0.99 or almost 1 in the mid-IR range in order to serve as a good re-emitter. For example, in some embodiments, the black intermediate layer 115 comprises Black 3.0™, Black 4.0™, Vantablack™ carbon nanotubes, or other ultra-black material. The structure and increased porosity of the black intermediate layer 115 may also provide better radial localization of heat and/or better thermal isolation.

The present disclosure contemplates that the black intermediate layer 115 may be applied to the substrate 110 by any number of methods. For example, in some embodiments, the black intermediate layer 115 is deposited on the front side of the substrate 110 using an airbrush paint sprayer. In a non-limiting example, a diluted solution of water-based Black 3.0™ or Black 4.0™ is sprayed, in air, in multiple passes onto the substrate 110 while the substrate 110 is rotated (e.g., via a Lazy Suzan) and while allowing to dry in-between applications so that the water does not puddle on the substrate 110 and in order to apply the black intermediate layer 115 uniformly. In another non-limiting example, Vantablack™ carbon nanotubes may be grown on the front side surface of the substrate 110 to form the black intermediate layer 115. In another non-limiting example, the black intermediate layer 115 is deposited on the front side of the substrate 110 via carbon black deposition, which is a vacuum deposition process.

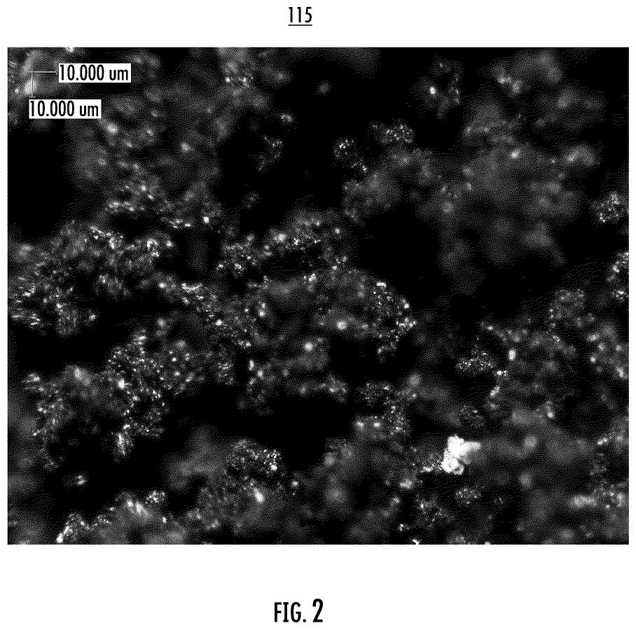

The present disclosure contemplates that the black intermediate layer 115 may be of any suitable thickness as needed for the specific diagnostic implementation. In some embodiments, thickness may be determined by observing the optical attenuation of a green laser pointer to be greater than 99%. In some embodiments, the substrate 110 is weighed before and after application of the black intermediate layer, the difference in mass indicating how much carbon material has been deposited onto the substrate 110. For example, in one embodiment, the black intermediate layer 115 may be determined to be about 5 μm equivalent thickness by weight if the carbon was solid, however, the black intermediate layer 115 as applied may be very rough (e.g., spiky, porous, and knobby), with a structure spatial scale of about 50 μm, as depicted in the optical microscope image of FIG. 2. That is, FIG. 2 depicts a black intermediate layer 115 comprising Black 3.0™ applied onto smooth sapphire, as seen under a microscope. Accordingly, the equivalent thickness of the black intermediate layer 115 of the present disclosure may be between 5 μm and 100 μm thick. For example, in some embodiments, the equivalent thickness of the black intermediate layer 115 is less than about 100 μm, less than about 95 μm, less than about 90 μm, less than about 85 μm, less than about 80 μm, less than about 75 μm, less than about 70 μm, less than about 65 μm, less than about 60 μm, less than about 55 μm, less than about 50 μm, less than about 45 μm, less than about 40 μm, less than about 35 μm, less than about 30 μm, less than about 25 μm, less than about 20 μm, less than about 15 μm, less than about 10 μm, less than about 9 μm, less than about 8 μm, less than about 7 μm, or less than about 6 μm.

In some embodiments, the equivalent thickness of the black intermediate layer 115 is greater than about 5 μm, greater than about 10 μm, greater than about 15 μm, greater than about 20 μm, greater than about 25 μm, greater than about 30 μm, greater than about 35 μm, greater than about 40 μm, greater than about 45 μm, greater than about 50 μm, greater than about 55 μm, greater than about 60 μm, greater than about 65 μm, greater than about 70 μm, greater than about 75 μm, greater than about 80 μm, greater than about 85 μm, greater than about 90 μm, greater than about 91 μm, greater than about 92 μm, greater than about 93 μm, greater than about 94 μm, greater than about 95 μm, greater than about 96 μm, greater than about 97 μm, greater than about 98 μm, or greater than about 99 μm.

As shown in FIG. 1, in some embodiments, the infrared imaging sensor 100 may comprise an x-ray absorber layer 120. In some embodiments, the x-ray absorber layer 120 is disposed onto the black intermediate layer 115. For example, in some embodiments, the x-ray absorber layer 120 is deposited on the front side of the black intermediate layer 115, which is the side facing the plasma in operation.

In some embodiments, the x-ray absorber layer 120 comprises a higher Z material, such as, but not limited to, gold, platinum, tantalum, tungsten, titanium, aluminum, etc. For example, in some embodiments, the x-ray absorber layer 120 comprises gold. In other embodiments, the x-ray absorber layer 120 comprises platinum. In still other embodiments, the infrared imaging sensor 100 comprises multiple x-ray absorber layers and each layer may be the same or different (e.g., first layer is gold and then a second layer of platinum, etc.). In some embodiments, portions of one or more x-ray absorber layers 120 comprise different Z materials. In a non-limiting example, an x-ray absorber layer 120 may be 25% covered in a first Z material, such as gold, and 45% covered in a second Z material, such as platinum.

The higher Z material functions as a good absorber of soft x-rays. The x-ray absorber layer 120 has a low or small heat capacity.

The present disclosure contemplates that the x-ray absorber layer 120 may be applied to the black intermediate layer 115 by any number of methods. For example, in some embodiments, the x-ray absorber layer 120 is overcoated onto the black intermediate layer 115 via a vacuum sputtering deposition process, which allows the x-ray absorber layer 120 to be applied in virtually any thickness.

The present disclosure contemplates that the x-ray absorber layer 120 may be of any suitable thickness as needed for the specific diagnostic implementation. In addition, the thickness of the x-ray absorber layer(s) 120 is otherwise sufficient to block contaminating infrared light through the front layer of the infrared imaging sensor 100 in its field of view. In some embodiments, the blocking of contaminated light needs to be less than 10-3 to 104.

In some embodiments, the thickness of the x-ray absorber layer 120 of the present disclosure may be between 1.0 μm and 5.0 μm thick. For example, in some embodiments, the thickness of the x-ray absorber layer 120 is less than about 5.0 μm, less than about 4.5 μm, less than about 4.0 μm, less than about 3.5 μm, less than about 3.0 μm, less than about 2.5 μm, less than about 2.0 μm, less than about 1.5 μm, less than about 1.4 μm, less than about 1.3 μm, less than about 1.2 μm, or less than about 1.1 μm.

In some embodiments, the thickness of the x-ray absorber layer 120 is greater than about 1.0 μm, greater than about 1.1 μm, greater than about 1.2 μm, greater than about 1.3 μm, greater than about 1.4 μm, greater than about 1.5 μm, greater than about 2.0 μm, greater than about 2.5 μm, greater than about 3.0 μm, greater than about 3.5 μm, greater than about 4.0 μm, greater than about 4.5 μm, greater than about 4.6 μm, greater than about 4.7 μm, greater than about 4.8 μm, or greater than about 4.9 μm. For example, in certain embodiments, the x-ray absorber layer 120 is approximately 2.0 μm thick.

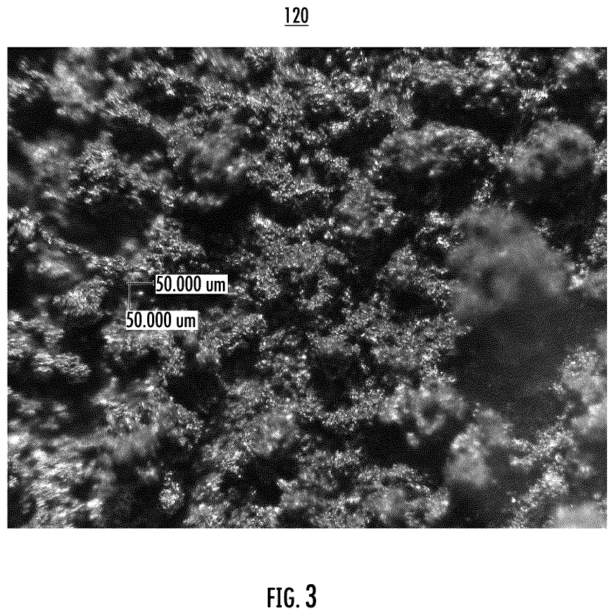

As depicted in FIG. 3, the resulting x-ray absorber layer 120 may have an extremely diffuse reflectivity (unlike a gold mirror surface) due to the roughness of the underlying black intermediate layer 115. In the optical microscope image of FIG. 3, an x-ray absorber layer 120 comprising approximately 2-micron gold coating has been applied on top of a black intermediate layer 115 of Black 3.0™. The spatial scale of the roughness in FIG. 3 is approximately 50 μm.

As shown in FIG. 1, in some embodiments, the infrared imaging sensor 100 may optionally comprise a blackening layer 125. In some embodiments, the blackening layer 125 is disposed onto the x-ray absorber layer 120. For example, in some embodiments, the blackening layer 125 is deposited on the front side of the x-ray absorber layer 120, which is the side facing the plasma during operation. Such a blackening layer 125 may be optionally applied to for better UV and visible light absorption. That is, the blackening layer 125 may help absorb UV and visible light which might otherwise be reflected by the x-ray absorber layer 120, thereby making the x-ray absorber layer 120 less reflective. In some embodiments, the infrared imaging sensor 100 does not comprise a blackening layer 125.

The present disclosure contemplates that the blackening layer 125 may comprise any of the materials that form the black intermediate layer 115. For example, the blackening layer 125 may comprise Black 3.0™, Black 4.0™, Vantablack™ carbon nanotubes, or other ultra-black material. The present disclosure also contemplates that the blackening layer 125 may be applied to the x-ray absorber layer(s) 120 by any of the same methods as the black intermediate layer 115.

The present disclosure contemplates that the optional blackening layer 125 may be of any suitable thickness as needed for the specific diagnostic implementation. In some embodiments, the thickness of the blackening layer 125 of the present disclosure may be between 0.1 μm and 5.0 μm thick. For example, in some embodiments, the thickness of the blackening layer 125 is less than about 5.0 μm, less than about 4.5 μm, less than about 4.0 μm, less than about 3.5 μm, less than about 3.0 μm, less than about 2.5 μm, less than about 2.0 μm, less than about 1.5 μm, less than about 1.0 μm, less than about 0.9 μm, less than about 0.8 μm, less than about 0.7 μm, less than about 0.6 μm, less than about 0.5 μm, less than about 0.4 μm, less than about 0.3 μm, or less than about 0.2 μm.

In some embodiments, the thickness of the blackening layer 125 is greater than about 0.1 μm, greater than about 0.2 μm, greater than about 0.3 μm, greater than about 0.4 μm, greater than about 0.5 μm, greater than about 0.6 μm, greater than about 0.7 μm, greater than about 0.8 μm, greater than about 0.9 μm, greater than about 1.0 μm, greater than about 1.5 μm, greater than about 2.0 μm, greater than about 2.5 μm, greater than about 3.0 μm, greater than about 3.5 μm, greater than about 4.0 μm, greater than about 4.5 μm, greater than about 4.6 μm, greater than about 4.7 μm, greater than about 4.8 μm, or greater than about 4.9 μm. In some embodiments, if present, the blackening layer 125 is thinner than the black intermediate layer 115.

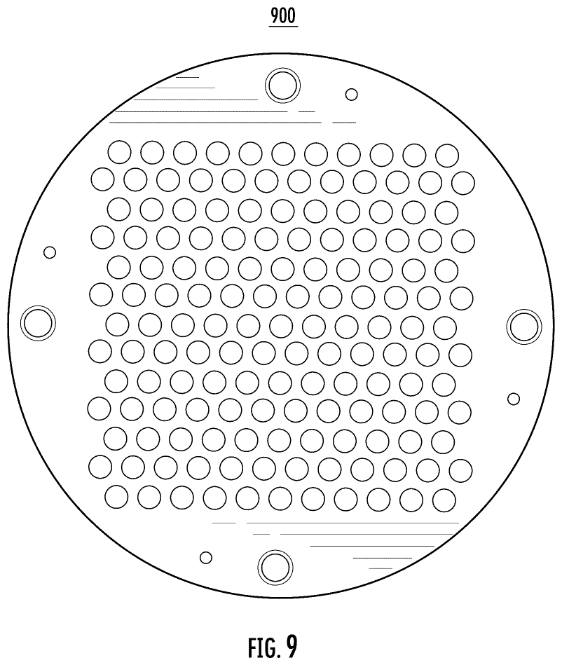

The infrared imaging sensor 100 of the present disclosure may optionally comprise one or more masks 900, an example of which is depicted in FIG. 9. A copper mask 900 may be optionally positioned at the top of the stack (e.g., the side facing the plasma) and may be a few millimeters thick with a grid pattern of holes. For example, in some embodiments, a mask 900 may comprise copper with an appropriate number of holes to form a segmented matrix. The mask(s) 900 may provide thermal isolation between adjacent macropixels or segments of the x-ray absorber layer 120. Such masking may assist in cooling the sensor as described herein with respect to the imaging bolometer. That is, the mask 900 may be water-cooled at the outer diameter and serve two functions: (1) to isolate bolometer macropixels from each other, thermally, and (2) provide a cooled reference temperature at the boundary of each micropixel, useful for long pulse operation where the long-term temperature rise of the substrate material may need to be controlled.

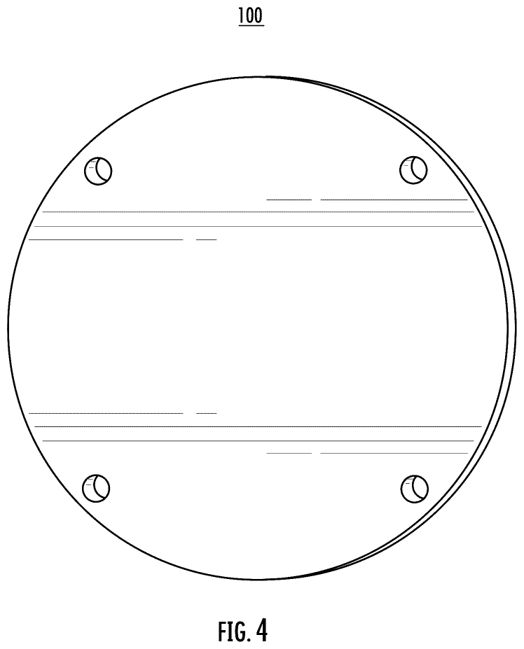

FIG. 4 depicts an example infrared imaging sensor 100 according to various embodiments of the present disclosure. As shown in FIG. 4, an infrared imaging sensor 100 comprises a multi-layer coated sapphire disk (135 mm diameter, 3 mm thick) with Black 3.0™, sputter-deposited gold, a thin layer of blackening, and four diamond-cut 6 mm diameter mounting holes.

The present disclosure contemplates that the infrared imaging sensor 100 may be incorporated as a sensor in an imaging bolometer. For example, an imaging bolometer may comprise an IR camera (e.g., mid-IR wavelength) arranged in a pinhole (e.g., 2-3 mm diameter) geometry with respect to the infrared imaging sensor 100, the infrared imaging sensor 100 disposed between the IR camera and the fusion plasma source with the anti-reflection coating 105 facing the IR camera and the x-ray absorber layer 120 (or blackening layer 125) facing the fusion plasma source. In some embodiments, the infrared imaging sensor 100 may be placed in an actively cooled (e.g., water cooled) copper holder, with the edges being cooled. Because the substrate (e.g., sapphire disk) operates as a large heat sink, there is less concern with melting in the center of the x-ray absorber layer of the infrared imaging sensor 100 as compared to the free-standing metal foil. One or more relay mirrors may be used since the IR camera may not be able to be located within a few meters of the plasma.

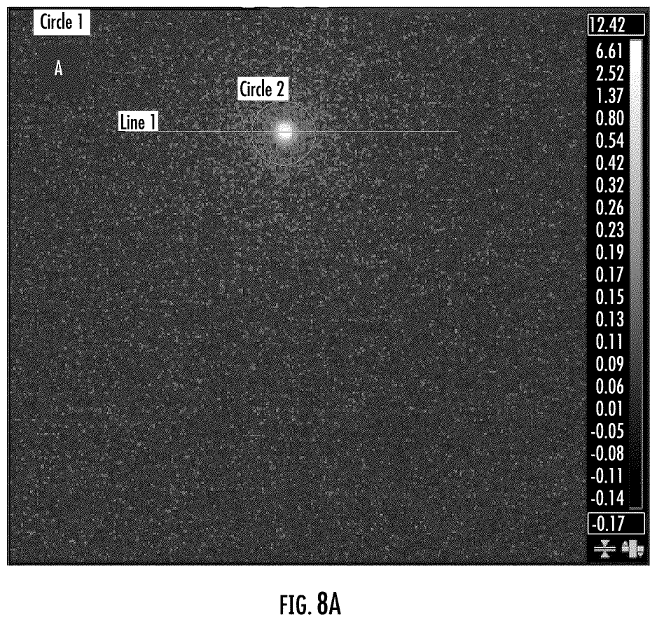

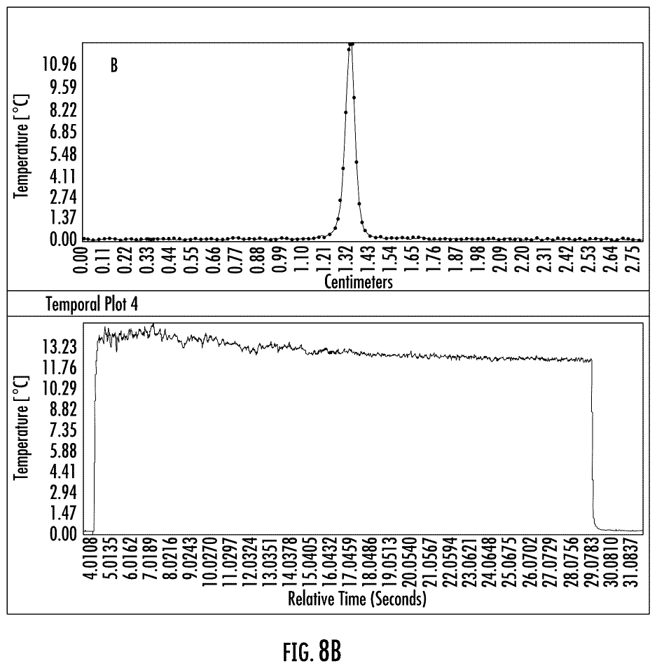

The present disclosure contemplates that the infrared imaging sensor 100 may be incorporated as a sensor in a single-frame calorimeter. For example, due to the decay time of an infrared imaging sensor 100 (as discussed with respect to FIGS. 8A and 8B) in accordance with example embodiments herein, the infrared imaging sensor 100 may be used to measure the integrated heat signal in one frame (e.g., the total energy deposited). As a single frame calorimeter, the pattern of the total energy deposited on the infrared imaging sensor 100 is read out up to the time resolution of the IR camera (e.g., at a 1 kHz frame rate). No information about the time evolution of the energy is possible, hence, this measurement is an example of calorimetry, as opposed to bolometry.

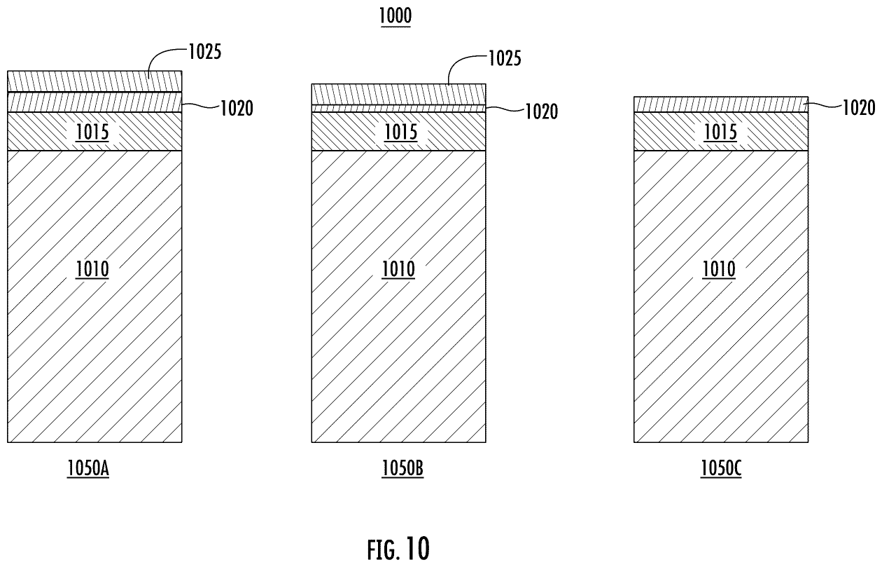

In accordance with another aspect of the present disclosure, FIG. 10 schematically depicts three example macropixels 1050A-1050C of an example energy resolving infrared imaging sensor 1000 used in an energy resolving imaging bolometer according to various embodiments of the present disclosure. As shown in FIG. 10, a portion of an example energy resolving infrared imaging sensor depicts three example adjacent macropixels 1050A-1050C, portions of which are coated differently to absorb or reflect specific radiation types to enable simultaneous imaging of distinct energy bands. For example, each of macropixels 1050A-1050C includes a substrate 1010 and a black intermediate layer 1015, similar to substrate 110 and black intermediate layer 115, respectively. In the first and third depicted macropixels 1050A and 1050C, an x-ray absorber layer 1020, similar to x-ray absorber layer 120, is formed on the black intermediate layer 1015. Such x-ray absorber layer 1020 is between 1.0 μm and 5.0 μm thick. For example, in some embodiments, the thickness of the x-ray absorber layer 1020 is less than about 5.0 μm, less than about 4.5 μm, less than about 4.0 μm, less than about 3.5 μm, less than about 3.0 μm, less than about 2.5 μm, less than about 2.0 μm, less than about 1.5 μm, less than about 1.4 μm, less than about 1.3 μm, less than about 1.2 μm, or less than about 1.1 μm. In the second depicted macropixel 1050B, a thin x-ray absorber layer 1020′ is formed on the black intermediate layer of macropixel 1050B. The thin x-ray absorber layer 1020′ is thinner compared to the x-ray absorber layer 1020. In some embodiments, the thin x-ray absorber layer 1020′ is approximately 1-25% the thickness of the x-ray absorber layer 1020. For example, in some embodiments, the thin x-ray absorber layer 1020′ is between 0.1 μm and 0.5 μm thick. For example, in some embodiments, the thickness of the thin x-ray absorber layer 1020′ is less than about 0.5 μm, less than about 0.45 μm, less than about 0.4 μm, less than about 0.35 μm, less than about 0.3 μm, less than about 0.25 μm, less than about 0.2 μm, less than about 0.15 μm, less than about 0.14 μm, less than about 0.13 μm, less than about 0.12 μm, or less than about 0.11 μm. In some embodiments, the thin x-ray absorber layer 1020′ is between 0.2 μm and 0.5 μm thick. In a non-limiting example embodiment, the x-ray absorber layer 1020 is 2 to 3 microns thick and the thin x-ray absorber layer 1020′ is approximately 0.5 microns. With continued reference to FIG. 10, each of the first and second depicted macropixels 1050A and 1050B include a blackening layer 1025 formed on the surface of the x-ray absorber layer 1020 and thin x-ray absorber layer 1020′, respectively. The third depicted macropixel 1050C does not include a blackening layer 1025.

The use of the x-ray absorber layer 1020 and the thin x-ray absorber layer 1020′ having differing thicknesses and the presence and absence of a blackening layer 1025 on adjacent or similarly located macropixels 1050A-1050C enables the differentiation of energy bands. For example, in the depicted example macropixel 1050A, the blackening layer 1025 will absorb visible and ultraviolet radiation and the x-ray absorber layer 1020 will absorb most of high- and low-energy x-rays of interest. Further, in the depicted example macropixel 1050B, the blackening layer 1025 will absorb visible and ultraviolet radiation and the thin x-ray absorber layer 1020′ will absorb most of the low-energy x-rays of interest, but high-energy x-rays will go through the thin x-ray absorber layer 1020′. Further still, without a blackening layer 1025, the x-ray absorber layer 1020 of the depicted example macropixel 1050C will reflect the visible and ultraviolet radiation and absorb most of high- and low-energy x-rays of interest. Accordingly, the differing thicknesses of the x-ray absorber layers 1020 and the thin x-ray absorber layer 1020′ are configured to differentiate the less energetic x-rays and the more energetic x-rays and the presence and absence of the blackening layer 1025 enables measurement of the visible and ultraviolet radiation in a simultaneous image, with each filtered image corresponding to different energy bands. Although only one group of three example adjacent macropixels 1050A-1050C are depicted in FIG. 10, the present disclosure contemplates any number of groups of any number of different adjacent macropixels 1050A-1050C. For example, one or more additional distinct macropixels with a thickness of the x-ray absorber layer different from x-ray absorber layer 1020 macropixels 1050A and 1050C and different from the thin x-ray absorber layer of 1020′ of macropixel 1050B can be formed in such macropixel grouping. Still further, any number of such macropixel groupings can be formed on a substrate 1010 to form an array of distinct macropixel groupings.

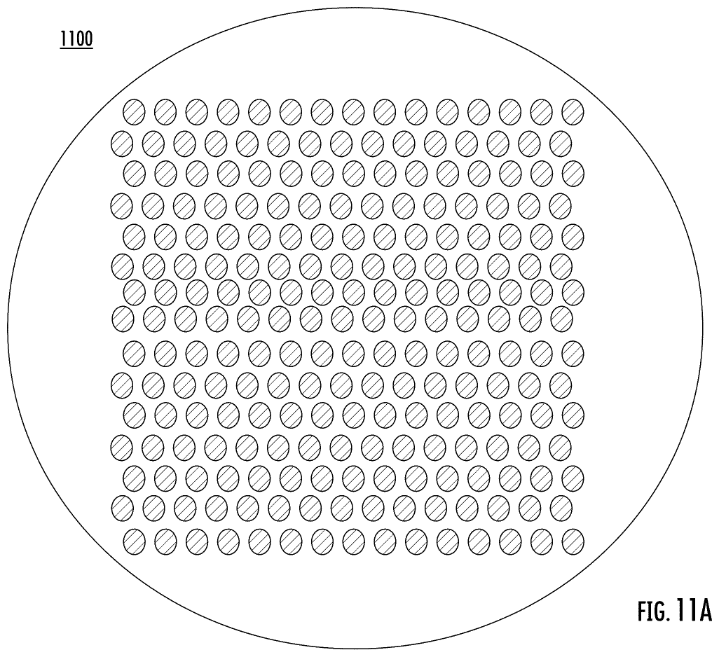

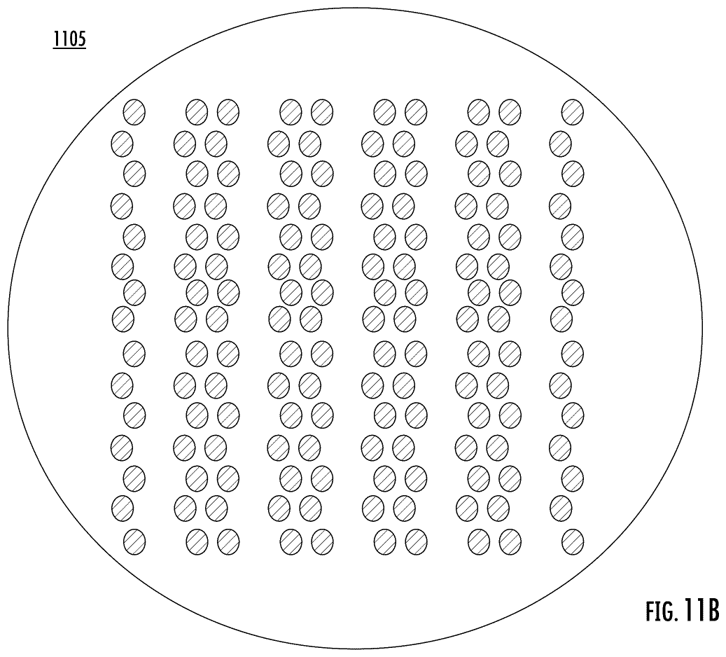

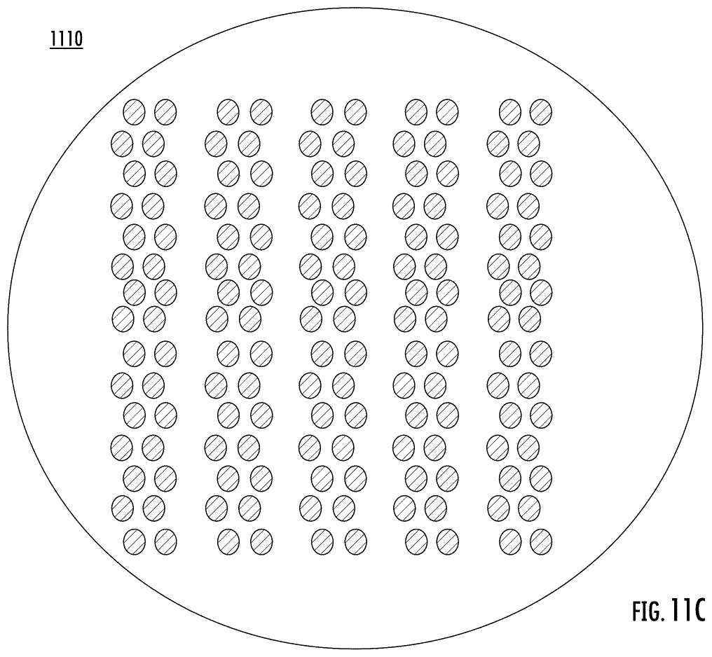

Such different macropixels 1050A-1050C may be fabricated in a number of ways. For example, in one embodiment, the different macropixels 1050A-1050C may be fabricated using a series of different masks. In such example embodiment, a substrate 1010 formed of a material that is optically transparent to mid-IR wavelengths and which provides sufficient mechanical support is provided, such as a sapphire disk, a diamond disk, a germanium disk, or a silicon disk. A black intermediate layer 1015 exhibiting a high blackbody emissivity in the IR wavelengths (2=1-12 μm), such as Black 3.0™, Black 4.0™, Vantablack™ carbon nanotubes, or other ultra-black material, is disposed on one side of the substrate 1010. In one embodiment, the black intermediate layer 1015 is applied to the entire first surface of the substrate 1010 that faces the radiation source (e.g., fusion plasma). In another embodiment, a mask such as the mask 1100 depicted in FIG. 11A is utilized, such that the application of the black intermediate layer 1015 to the first surface of the substrate 1010 forms an array of isolated portions containing the material of the black intermediate layer 1015. The depicted mask 1100 of FIG. 11A provides an array or matrix of 15×15 holes used to form 225 isolated portions, however, the present disclosure contemplates any size array or matrix of holes to form any number of isolated portions on the substrate 1010.

A combination of masks may be used to form the x-ray absorber layers 1020 and the thin x-ray absorber layer 1020′ of example macropixels 1050A-1050C. For example, in one embodiment, the depicted mask 1100 of FIG. 11A can be used to form a first layer of the x-ray absorber layer material (e.g., a high-z atomic number material such as gold, platinum, tantalum, tungsten, or the like) for each of macropixels 1050A-1050C, the first layer of the x-ray absorber layer material forming the thin x-ray absorber layer 1020′ of example macropixel 1050B, followed by the use of depicted mask 1105 of FIG. 11B to form a second layer of the x-ray absorber layer material on macropixels 1050A and 1050C, thereby forming the thicker x-ray absorber layers 1020 of macropixels 1050A and 1050C. For example, the depicted mask 1100 of FIG. 11A is used to form a first layer of the x-ray absorber layer material approximately 0.5 microns thick on the first surface (e.g., surface that faces the radiation source) of the black intermediate layer 1015 of each isolated portion depicted in the mask 1100 and the depicted mask 1105 of FIG. 11B is used to form a second layer of the x-ray absorber layer material approximately 1.5-2.5 microns thick on the first surface of the black intermediate layer of each isolated portion depicted in the mask 1105. As depicted in FIG. 11B, although masks 1100 and 1105 align, the depicted mask 1105 does not contain the same number of holes or apertures as mask 1100 such that the second layer of the x-ray absorber layer material is not applied as part of the macropixel 1050B. In other words, an x-ray absorber layer 1020 approximately 2-3 microns thick is formed as part of the first macropixel 1050A and third macropixel and a thin x-ray absorber layer 1020′ approximately 0.5 microns thick is formed as part of the macropixel 1050B. In an alternative embodiment, although not depicted, a mask opposite to or the reverse of (i.e., without holes or apertures for forming the array of macropixels corresponding to macropixels 1050A and 1050C) the depicted mask 1105 may be used to apply a thin layer of x-ray absorber layer material to form the array of macropixels corresponding to macropixel 1050B and then the depicted mask 1105 may be used to apply a thick layer of x-ray absorber layer material to form the array of macropixels corresponding to macropixels 1050A and 1050C (i.e., such that no additional x-ray absorber layer material is applied to the array of macropixels corresponding to macropixel 1050B). With reference to FIG. 11C, the depicted mask 1110 is then utilized to form a blackening layer 1025 only with respect to the array of macropixels corresponding to macropixels 1050A and 1050B, such that no blackening layer material is applied to the array of macropixels corresponding to macropixel 1050C. The blackening layer 1025, like blackening layer 125, comprises any of the materials that form the black intermediate layer 1015, 115. For example, the blackening layer 1025 may comprise Black 3.0™, Black 4.0™, Vantablack™ carbon nanotubes, or other ultra-black material.

The resulting filtered images generated by an energy resolving imaging bolometer using an energy resolving infrared imaging sensor 1000 formed using the masks 1100, 1105, 1110 would correspond to different energy bands of the radiation providing additional, distinctive information compared to a conventional bolometer or imaging bolometer using a single large pixel or an array of similarly-formed macropixels. For example, the arrangement of radiation types (e.g., from which portions to visible radiation and UV radiation extend compared to x-rays) extending from fusion plasma may be distinguished using an energy resolving imaging bolometer according to the present disclosure.

### Example Methods

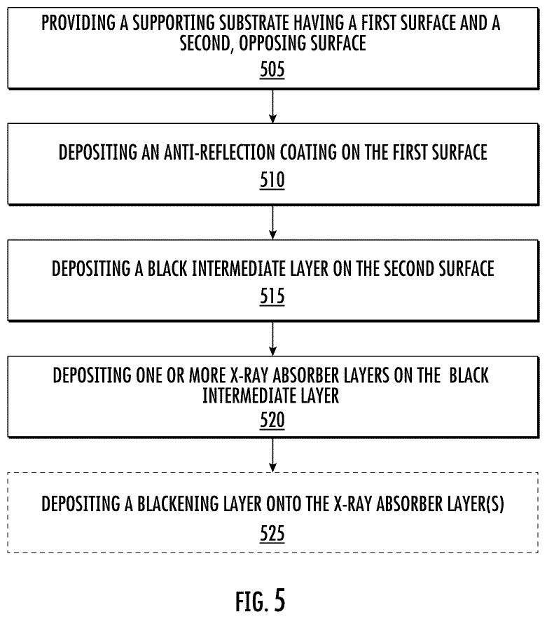

Having described the exemplary robust infrared imaging sensor of the present disclosure, it should be understood that the infrared imaging sensor may be fabricated in a number of ways. FIG. 5 is a flowchart broadly illustrating a series of steps that are performed to fabricate an infrared imaging sensor of the present disclosure, for example, the infrared imaging sensor 100 as described above.

As shown in step 505, a supporting substrate having a first surface and a second, opposing surface is provided. For example, in some embodiments, a sapphire disk is provided. Other substrate materials, such as diamond, diamond, germanium, or silicon are contemplated by the disclosure and can be used without deviating from this disclosure. A sapphire window disposed in a vacuum flange is also contemplated as the supporting substrate.

As shown in step 510, an anti-reflection coating is deposited on the first surface of the supporting substrate. For example, the anti-reflection coating may be deposited on the first surface of the supporting substrate in a deposition facility in vacuum.

As shown in step 515, a black intermediate layer is applied to the second surface of the supporting substrate. For example, in some embodiments, the black intermediate layer comprises Black 3.0™, Black 4.0™, Vantablack™ carbon nanotubes, or other ultra-black material. In some embodiments, the black intermediate layer is deposited via multi-passes using an airbrush paint sprayer. In another non-limiting example, Vantablack™ carbon nanotubes may be grown on the second surface of the supporting substrate to form the black intermediate layer. In another non-limiting example, the black intermediate layer is deposited on the second surface of the supporting substrate via carbon black deposition, which is a vacuum deposition process.

As shown in step 520, one or more x-ray absorber layers are applied onto the black intermediate layer. For example, in some embodiments, an x-ray absorber layer comprises a higher Z material, such as, but not limited to, gold, platinum, tantalum, tungsten, titanium, aluminum, etc. For example, in some embodiments, the x-ray absorber layer comprises gold. In other embodiments, the x-ray absorber layer comprises platinum. In still other embodiments, multiple x-ray absorber layers are applied onto the black intermediate layer and each layer may be the same or different (e.g., first layer is gold and then a second layer of platinum, etc.). The x-ray absorber layer(s) may be overcoated onto the black intermediate layer via a vacuum sputtering deposition process, which allows the x-ray absorber layer to be applied in virtually any thickness. The thickness of the x-ray absorber layer(s) may be thick enough to stop/capture soft x-rays and thin enough to have a sufficiently detectable temperature rise.

As shown in step 525, a blackening layer is optionally applied onto the x-ray absorber layer(s). For example, the optional blackening layer comprises Black 3.0™, Black 4.0™ Vantablack™ carbon nanotubes, or other ultra-black material. In some embodiments, the optional blackening layer is deposited via an airbrush paint sprayer. In another example, Vantablack™ carbon nanotubes may be grown on the x-ray absorber layer(s) formed in step 520. In another example, the blackening layer is deposited via carbon black deposition, which is a vacuum deposition process.

### Example Infrared Imaging Sensors and Instruments

The following examples are offered by way of illustration and not by way of limitation. Those skilled in the art will appreciate that other routes may be used to apply each layer of the infrared imaging sensors described herein. Although specific thicknesses and materials are depicted and discussed in the Example, other thicknesses and materials can be easily substituted to provide a variety of infrared imaging sensors.

### Example 1: Preparation of IR Imaging Sensor-Multi-Layer Coated Sapphire Disk

To prepare the sensor, a flat piece of sapphire (135 mm diameter, 3 mm thick sapphire disk) is first anti-reflection coated for 3-5 micron light wavelengths on the side that will be facing the IR camera. Then, on the other side, using an artist's airbrush paint sprayer and multiple passes, a diluted solution of water-based Black 3.0™ is sprayed onto the disk, while it is rotated on a lazy suzan for uniformity. The coating is allowed to dry in-between applications. The equivalent thickness (as measured by weight) of the very rough coating is approximately 5 μm. Over approximately 30 minutes, a 2 μm thick coating of gold is sputter deposited onto the intermediate Black 3.0™ coating. An additional thin layer of Black 3.0™ is overcoated onto the gold layer. The resulting multi-layer coated sapphire disk forming the IR imaging sensor is depicted in FIG. 4 with four diamond-cut 6 mm diameter mounting holes.

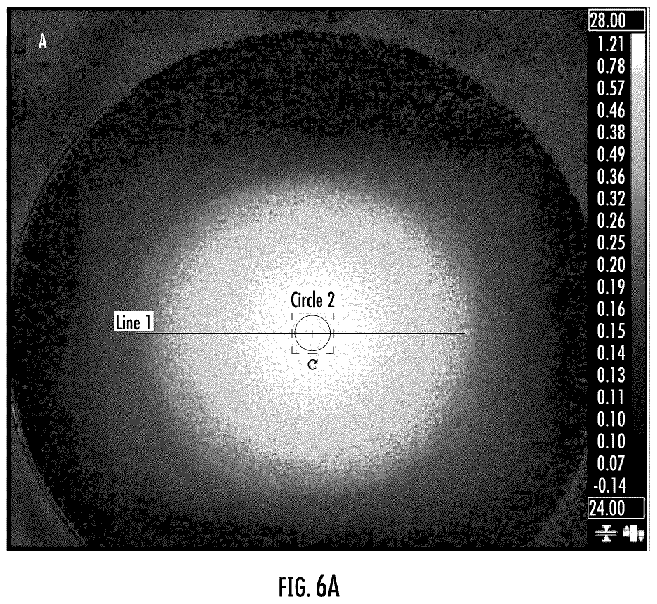

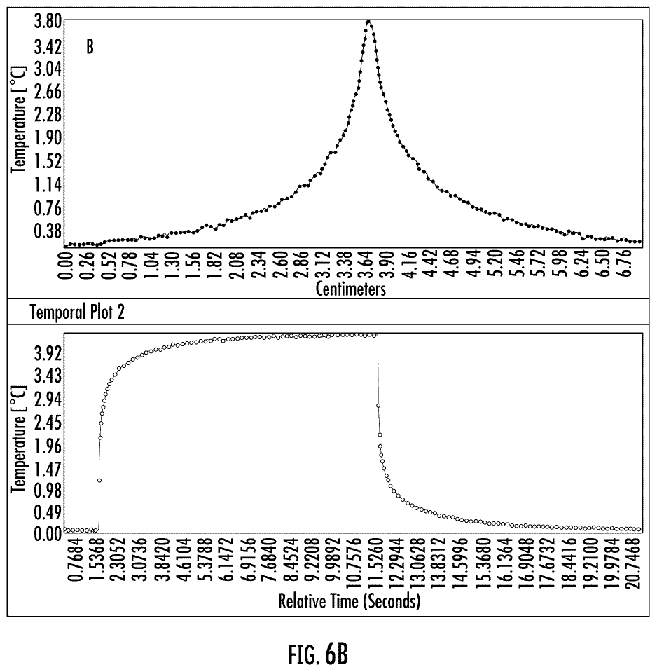

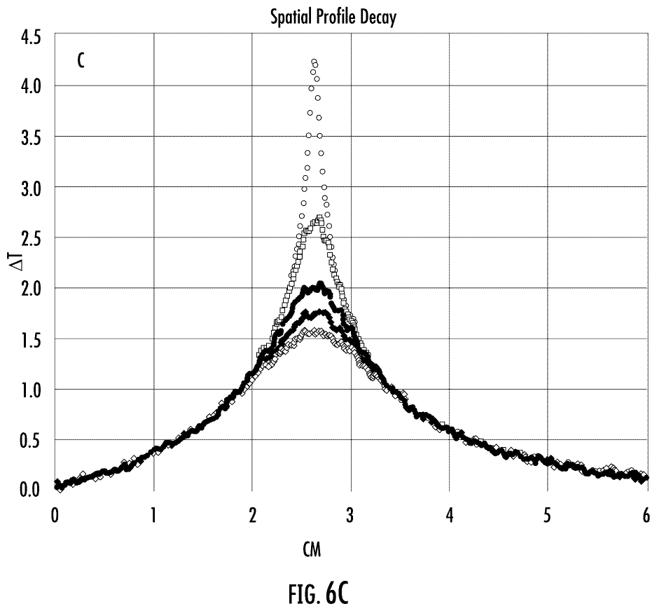

FIGS. 6A-6C show performance data for a conventional (7 cm×9 cm rectangular foil) 5 μm thick blackened gold foil in vacuum. Using a cooled FLIR camera operating at 3-5 micron IR wavelengths, FIG. 6A depicts a steady-state IR image showing the temperature spreading on the rectangular foil when illuminated with an 18 mW blue laser. FIG. 6B depicts spatial profile (top) and temporal response (bottom) of the rectangular foil to a pulsed laser diode. Because the thermal diffusivity of gold is high (1.27×10⁻⁴ m²/sec), the small circular (˜2 mm diameter) applied laser heat pulse quickly diffused onto the large foil, while the foil was also cooling by blackbody radiation. FIG. 6C depicts the spatial profile decay of the rectangular foil as laser is turned off, shown over four consecutive 30-millisecond time steps.

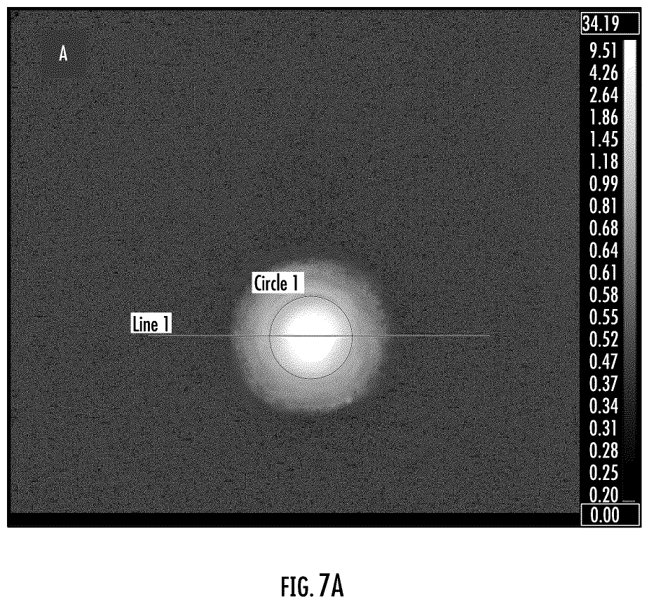

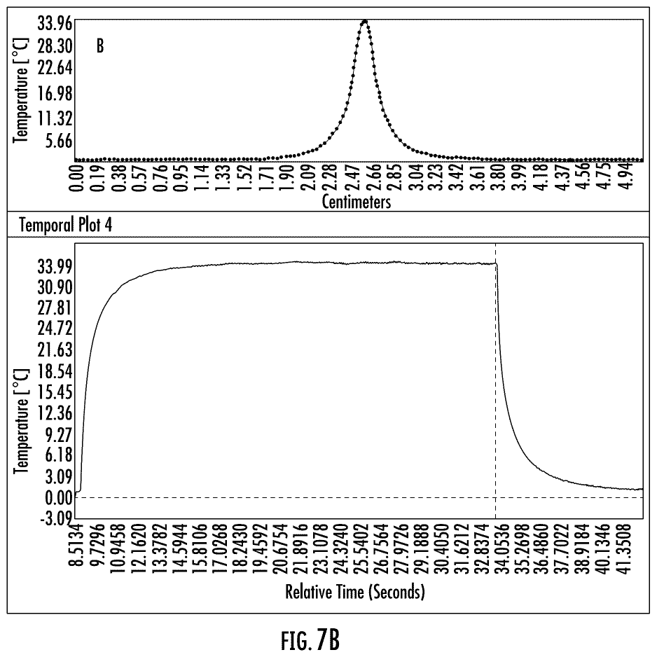

FIGS. 7A and 7B show performance data for a conventional (˜0.7 μm thick) platinum foil, blackened on both sides with Black 3.0™, in vacuum. Using a cooled FLIR camera operating at 3-5 micron IR wavelengths, FIG. 7A depicts a steady-state IR image showing the temperature change on the foil when illuminated with a 9 mW red laser. The peak ΔT (34° C.) was much higher than the gold foil depicted in FIGS. 6A-6C, due to thinness of the platinum foil and the smaller heat capacity and smaller thermal diffusivity (2.6×10⁻⁵ m²/sec) of platinum. The signal drops to 10% ΔT at 9 mm diameter circle. FIG. 7B depicts spatial profile (top) and temporal response (bottom) of the foil of to a pulsed laser diode.

FIGS. 8A and 8B show performance data for the resulting multi-layer coated sapphire disk of Example 1 forming an infrared imaging sensor consistent with embodiments of the present disclosure. Using a cooled FLIR camera operating at 3-5 micron IR wavelengths, FIG. 8A depicts a steady-state IR image showing the temperature change on the multi-layer coated sapphire disk when illuminated with 21 mW blue laser. The sensitivity is less than the gold foil depicted in FIGS. 6A-6C, but there is essentially no lateral diffusion in Example 1. The temperature spot simply decays in time, without spreading since the axial cooling into the sapphire disk dominates. In addition, while not being restricted by theory, the inventor believes the roughness of the intervening (and insulating) carbon layer may inhibit lateral spreading as well since transport distances across the disk from local peaks in the rough coating to adjacent local peaks are longer than directly down to the sapphire disk. For example, by preventing or reducing lateral heat movement due to the rough carbon layer and/or the thick substrate (e.g., an infinitely thick heat sink with high heat capacity compared to the thin coatings having little to no heat capacity), a tight, radially localized image is achievable. FIG. 8B depicts spatial profile (top) and temporal response (bottom) of the multi-layer coated sapphire disk to a pulsed laser diode. The 1.5 mm diameter spot is essentially the laser spot diameter. Advantageously, when the laser is turned off, the decay time for the sapphire disk-based sensor of the present disclosure is very fast compared to the platinum and gold foils, which are much slower, which allows for better time resolution with the sapphire disk-based sensor.

Thus, particular embodiments of the subject matter have been described. While this specification contains many specific implementation details, these should not be construed as limitations on the scope of any embodiments or of what may be claimed, but rather as description of features specific to particular embodiments of the present disclosure. Other embodiments are within the scope of the following claims. It is evident that many alternatives, modifications, and variations will be apparent to those skilled in the art in light of the foregoing description. It is therefore contemplated that the appended claims will embrace any such alternatives, modifications, and variations as falling within the scope and spirit of the present disclosure.

Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while steps or processes are depicted in the drawings in a particular order, this should not be understood as requiring that such steps or processes be performed in the particular order shown or in sequential order, or that all illustrated steps or processes be performed, to achieve desirable results, unless described otherwise. Said differently, the actions recited in the claims can be performed in a different order and still achieve desirable results. In addition, the processes depicted in the accompanying figures do not necessarily require the particular order shown, or sequential order, to achieve desirable results, unless described otherwise. In certain implementations, multitasking and parallel processing may be advantageous.

### Overview of Terms

For the purposes of the present application, the following explanations of terms are provided to better describe the present disclosure and to guide those of ordinary skill in the art in the practice of the present disclosure:

As used herein, the term “comprising” means including but not limited to and should be interpreted in the manner it is typically used in the patent context. Use of broader terms such as “comprises”, “includes”, and “having” should be understood to provide support for narrower terms such as “consisting of”, “consisting essentially of”, and “comprised substantially of”.

As used herein, the phrases “in one embodiment,” “according to one embodiment,” “in some embodiments,” and the like generally refer to the fact that the particular feature, structure, or characteristic following the phrase may be included in at least one embodiment of the present disclosure. Thus, the particular feature, structure, or characteristic may be included in more than one embodiment of the present disclosure such that these phrases do not necessarily refer to the same embodiment.

As used herein, the terms “illustrative,” “example,” “exemplary” and the like are used to mean “serving as an example, instance, or illustration” with no indication of quality level. Any implementation described herein as “exemplary” or “example” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that particular component or feature is not required to be included or to have the characteristic. Such component or feature may be optionally included in some embodiments, or it may be excluded.

The terms “about,” “approximately,” “generally,” “substantially,” or the like, when used with a number, may mean that specific number, or alternatively, a range in proximity to the specific number, as understood by persons of skill in the art field and may be used to refer to within manufacturing and/or engineering design tolerances for the corresponding materials and/or elements as would be understood by the person of ordinary skill in the art, unless otherwise indicated.

It is understood that where a parameter range is provided, all integers and ranges within that range, and tenths and hundredths thereof, are also provided by the embodiments. For example, “5-10%” includes 5%, 6%, 7%, 8%, 9%, and 10%; 5.0%, 5.1%, 5.2% . . . 9.8%, 9.9%, and 10.0%; and 5.00%, 5.01%, 5.02% . . . 9.98%, 9.99%, and 10.00%, as well as, for example, 6-9%, 5.1%-9.9%, and 5.01%-9.99%. Similarly, where a list is presented, unless stated otherwise, it is to be understood that each individual element of that list, and every combination of components of that list, is a separate embodiment. For example, “1, 2, 3, 4, and 5” encompasses, among numerous embodiments, 1; 2; 3; 1 and 2; 3 and 5; 1, 3, and 5; and 1, 2, 4, and 5.

The term “plurality” refers to two or more items.

The term “set” refers to a collection of one or more items.

The term “or” is used herein in both the alternative and conjunctive sense, unless otherwise indicated.

### CONCLUSION

Many modifications and other embodiments of the present disclosure set forth herein will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. An infrared imaging sensor comprising:
a substrate;
one or more x-ray absorber layers; and
a black intermediate layer disposed between the substrate and the one or more x-ray absorber layers.

2. The infrared imaging sensor of claim 1, wherein the substrate comprises sapphire, diamond, germanium, or silicon.

3. The infrared imaging sensor of claim 1, wherein the substrate is approximately 1-3 mm thick.

4. The infrared imaging sensor of claim 1, wherein the one or more x-ray absorber layers comprise a high-z material.

5. The infrared imaging sensor of claim 4, wherein the one or more x-ray absorber layers comprise gold, platinum, tungsten, or tantalum.

6. The infrared imaging sensor of claim 4, wherein the one or more x-ray absorber layers are approximately 1-5 microns thick.

7. The infrared imaging sensor of claim 1, wherein the infrared imaging sensor comprises a plurality of macropixels, a first set of the plurality of macropixels comprising a first x-ray absorber layer of the one or more x-ray absorber layers and a second set of plurality of macropixels comprising a second x-ray absorber layer of the one or more x-ray absorber layers, wherein the second x-ray absorber layer is thinner than the first x-ray absorber layer.

8. The infrared imaging sensor of claim 7, wherein the first x-ray absorber layer is approximately 2-3 microns thick and the second x-ray absorber layer is approximately 0.2-0.5 microns thick.

9. The infrared imaging sensor of claim 7, wherein the second x-ray absorber layer is disposed between the black intermediate layer and a blackening layer.

10. The infrared imaging sensor of claim 7, wherein a first subset of the first x-ray absorber layer is disposed between the black intermediate layer and a blackening layer.

11. The infrared imaging sensor of claim 1, wherein the black intermediate layer comprises Black 3.0™, Black 4.0™, or Vantablack™.

12. The infrared imaging sensor of claim 1, wherein the black intermediate layer has an equivalent thickness of 5-100 microns.

13. The infrared imaging sensor of claim 1, wherein the black intermediate layer has an equivalent thickness of approximately 5 microns.

14. The infrared imaging sensor of claim 1, further comprising:
an anti-reflection coating disposed on a side of the substrate opposite the one or more x-ray absorber layers and black intermediate layer.

15. The infrared imaging sensor of claim 1, further comprising:
a blackening layer, wherein the one or more x-ray absorber layers are disposed between the black intermediate layer and the blackening layer and wherein the blackening layer is approximately 0.1-5 microns thick.

16. The infrared imaging sensor of claim 15, wherein the blackening layer is thinner than the black intermediate layer.

17. A method of forming an infrared imaging sensor, the method comprising:
providing a supporting substrate, the supporting substrate having a first surface and a second, opposing surface;
depositing an anti-reflection coating on the first surface of the supporting substrate;
depositing a black intermediate layer on the second, opposing surface of the supporting substrate; and
depositing one or more x-ray absorber layers onto the black intermediate layer.

18. The method of claim 17, further comprising:
depositing a blackening layer onto the one or more x-ray absorber layers.

19. The method of claim 17, wherein depositing the one or more x-ray absorber layers onto the black intermediate layer comprises overcoating a high-Z material onto the black intermediate layer via a vacuum sputtering deposition process.

20. An imaging bolometer comprising:
an IR camera;
a pinhole;
one or more relay mirrors; and
an infrared imaging sensor, the infrared imaging sensor comprising:
a substrate, wherein the substrate comprises a sapphire disk;
one or more x-ray absorber layers; and
a black intermediate layer disposed between the substrate and the one or more x-ray absorber layers.
